(19) United States
(12) Patent Application Publication
(10) Pub. No.: US 2026/0006817 A1
(43) Pub. Date: Jan. 1, 2026

(54) METHOD FOR MANUFACTURING TRENCH MOSFET DEVICE

(71) Applicant: Magnachip Semiconductor, Ltd., Cheongju-si (KR)

(72) Inventors: Mi Rang PARK, Cheongju-si (KR); Do Eun LEE, Cheongju-si (KR); Jin Woo KIM, Cheongju-si (KR); Kyo Jun SIM, Cheongju-si (KR); Jun Hyun KIM, Cheongju-si (KR); Jae Yeong KIM, Cheongju-si (KR)

(73) Assignee: Magnachip Semiconductor, Ltd., Cheongju-si (KR)

(21) Appl. No.: 19/049,706

(22) Filed: Feb. 10, 2025

(30) Foreign Application Priority Data
Jun. 27, 2024 (KR) 10-2024-0084786

(51) Int. Cl. H10D 30/01; H10D 64/01

(52) U.S. Cl. CPC H10D 30/025; H10D 64/027

(57) ABSTRACT

A method for manufacturing a trench MOSFET device includes forming a trench in an epitaxial layer, forming a shield oxide and a shield poly in the trench, etching the shield poly to leave only a portion of the shield poly, forming an inter poly oxide (IPO) on the shield oxide and shield poly, etching the IPO and the shield oxide, leaving a portion of the IPO on an upper surface of the shield poly and the shield oxide, forming a first gate sacrificial oxide layer by performing a deposition process, forming a second gate sacrificial oxide layer on the first gate sacrificial oxide layer by performing a thermal oxidation process, and performing an etching process to leave a gate sacrificial oxide layer at a boundary between a sidewall of an interior of the trench and the upper surface of the shield oxide.

### CROSS-REFERENCE TO RELATED APPLICATION

This application claims the benefit under 35 U.S.C. § 119(a) of Korean Patent Application No. 10-2024-0084786, filed on Jun. 27, 2024, in the Korean Intellectual Property Office, the entire disclosure of which is incorporated herein by reference for all purposes.

### BACKGROUND

### 1. Field

The present disclosure relates to a method of manufacturing a trench metal-oxide semiconductor field effect transistor (trench MOSFET) device and, in particular to a method of forming the bottom edge of a trench into a smooth arc shape prior to forming a gate oxide in the trench.

### 2. Description of the Related Art

A trench MOSFET is a type of transistor in which a channel is formed vertically and a gate is formed in a trench extending between a source and a drain.

In a conventional process, a sacrificial oxide film is first deposited in the trench before forming an insulating film, and then the sacrificial oxide is removed by an etching process. The etching process typically employs partial dry etching.

However, when the sacrificial oxide is removed by partial dry etching, the plasma used for dry etching tends to concentrate at the bottom edge of the inner sidewall of the trench. This results in the formation of a concave curvature at the bottom edge. As a result, when the insulating film of the gate oxide is formed in the trench during the subsequent process, the thickness of the gate oxide at the bottom edge of the trench is not uniform. This causes problems such as a decrease in the gate-source breakdown voltage (BVGSS) of the gate oxide and an increase in the leakage current (IGSS) between the gate and source electrodes, which negatively affects the performance of the trench MOSFET device.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method for manufacturing a trench MOSFET device includes: forming an epitaxial layer on a semiconductor substrate; forming a trench in the epitaxial layer; forming a shield oxide and a shield poly in the trench; etching the shield poly in the trench to leave only a portion of the shield poly; forming an inter poly oxide (IPO) on the shield oxide and the shield poly; etching the IPO and the shield oxide in the trench, leaving a portion of the IPO on an upper surface of the shield poly and the shield oxide; forming a first gate sacrificial oxide layer having a first thickness upper surfaces of the epitaxial layer, the IPO, and the shield oxide in the trench by performing a deposition process; forming a second gate sacrificial oxide layer having a second thickness thinner than the first thickness on the first gate sacrificial oxide layer by performing a thermal oxidation process; and performing an etching process to leave a gate sacrificial oxide layer at a boundary between a sidewall of an interior of the trench and the upper surface of the shield oxide.

The first gate sacrificial oxide layer may be formed by performing a high-temperature low-pressure deposition (HLD) process.

The manufacturing method may further include: forming a gate oxide in the interior of the trench and on the upper surface of the epitaxial layer, with the gate sacrificial oxide layer formed at the boundary between the sidewall of the interior of the trench and the upper surface of the shield oxide; forming a gate poly on the gate oxide; forming a body region at an upper outer part of the trench; and forming a source region above the body region and a body contact region in the body region.

In the etching of the shield poly, a thickness of the IPO may be determined by a depth to which the shield poly is etched.

A thickness of the IPO may be adjusted in the etching of the IPO and the shield oxide.

The gate sacrificial oxide layer may be formed in an arc shape with a predetermined inclination angle at the boundary between the sidewall of the interior of the trench and the upper surface of the shield oxide.

The second gate sacrificial oxide layer may be formed using one of thermal oxidation methods of dry oxidation, wet oxidation, or steam oxidation.

Etching of areas other than the boundary between the sidewall of the interior of the trench and the upper surface of the shield oxide may be performed using wet etching.

A solution used for the wet etching may be a mixture of HF and NH₄F.

The manufacturing method may include etching a portion of the shield oxide formed on the sidewall of the trench that does not come into contact with the shield poly to expand an inlet width of the shield oxide.

The first thickness may be in a range of 300 Å to 1500 Å, and the second thickness is in a range of 200 Å to 600 Å.

The gate oxide may be formed by a thermal oxidation process or a combination of the thermal oxidation process and the HLD process.

An upper surface of the gate poly may be formed higher than an upper surface of the body region.

The semiconductor substrate, the epitaxial layer, and the source region may be formed with a first conductivity type, and the body region and the body contact region may be formed with a second conductivity type different from the first conductivity type.

In another general aspect, a method for manufacturing a trench MOSFET device includes: forming an epitaxial layer on a semiconductor substrate; forming a first trench in the epitaxial layer; forming a shield oxide and a shield poly in the first trench; etching a portion of the shield oxide to form a second trench on a side surface of the shield poly; forming a first gate sacrificial oxide layer having a first thickness in an interior of the second trench and on an upper surface of the epitaxial layer by performing a deposition process; forming a second gate sacrificial oxide layer having a second thickness thinner than the first thickness on the first gate sacrificial oxide layer by performing a thermal oxidation process; and performing an etching process to leave a gate sacrificial oxide layer at a boundary between a sidewall of the interior of the second trench and an upper surface of the shield oxide.

The etching may be performed by wet etching.

The first gate sacrificial oxide layer may be deposited by performing a high-temperature low-pressure deposition (HLD) process.

The manufacturing method may further include: forming a gate oxide in the interior of the second trench and on the upper surface of the epitaxial layer to cover the gate sacrificial oxide layer; forming a gate poly on the gate oxide; forming a body region at an upper outer portion of the first trench; and forming a source region above the body region and a body contact region in the body region.

The first thickness may be in a range of 300 Å to 1500 Å, and the second thickness may be in a range of 200 Å to 600 Å.

The second gate sacrificial oxide layer may be formed formed using one of the thermal oxidation methods of dry oxidation, wet oxidation, or steam oxidation.

Other features and aspects will be apparent from the following detailed description, the drawings, and the claims.

### BRIEF DESCRIPTION OF THE DRAWINGS

FIGS. 1 to 12 are process diagrams illustrating a method for manufacturing a trench MOSFET device according to a preferred example of the present disclosure.

FIGS. 13 and 14 are SEM cross-sectional photographs showing a comparison between the structure of the trench MOSFET device of the present disclosure and that of a conventional trench MOSFET device.

FIG. 15 is a graph illustrating a performance comparison between a trench MOSFET device of the present disclosure and a conventional trench MOSFET device.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The present disclosure is provided to solve the aforementioned problems and provides a method for manufacturing a trench MOSFET device in which the bottom corner of the trench interior is formed into a smooth arc-shaped contour with a gentle angle.

The present disclosure further provides a method for manufacturing a trench MOSFET device to prevent unnecessary thickening of an insulating film that forms at the bottom corner of the trench interior.

The technical objectives of the present disclosure are not limited to those mentioned above. Additional technical objectives not explicitly stated will be clearly understood by those skilled in the art from the description provided below.

A detailed description is provided below, referring to the drawings.

For the sake of convenience, the drawings illustrate only one trench formed in the epitaxial layer in the examples of the present disclosure. However, it should be understood that the present disclosure is also applicable to a structure in which one trench and at least one other trench are formed together in the epitaxial layer, with the latter being spaced at a predetermined distance from the first trench.

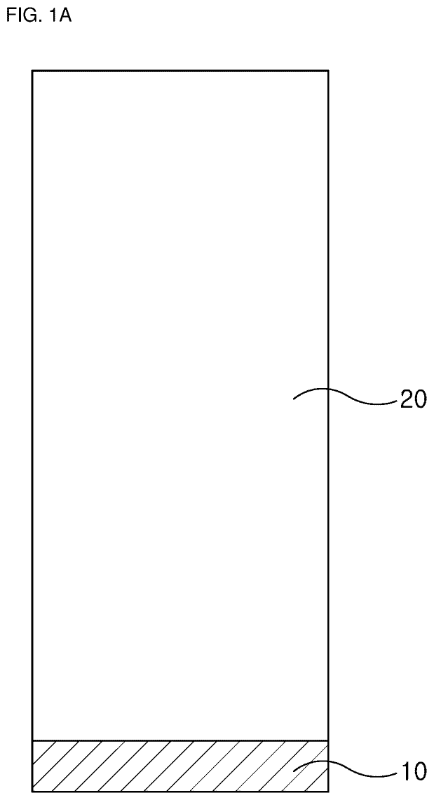

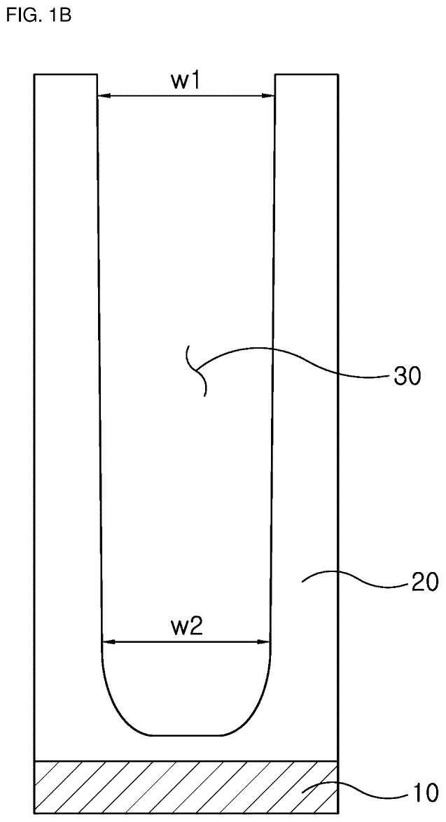

FIG. 1 to FIG. 12 are process diagrams illustrating a method for manufacturing a trench MOSFET device according to a preferred example of the present disclosure.

Referring to FIG. 1A, an epitaxial layer 20 is formed on a semiconductor substrate 10. In this example, both the semiconductor substrate 10 and the epitaxial layer 20 may be formed with the same first conductivity type, for example, N-type conductivity. The epitaxial layer 20 may be formed as a single layer or as two or more layers. Although not illustrated in the drawings, if the epitaxial layer 20 includes two layers, it may include a lower epitaxial layer formed on the semiconductor substrate 10 and an upper epitaxial layer formed on the lower epitaxial layer. In such a case, the first conductivity type of dopant in the semiconductor substrate 10 may diffuse during the subsequent thermal process. Depending on the degree of diffusion, the dopant concentration in the upper epitaxial layer may be lower than that in the lower epitaxial layer, resulting in a higher resistivity in the upper epitaxial layer. This configuration allows for a low on-resistance (Rdson) between the drain and the source.

In this example, even if the epitaxial layer 20 is formed of multiple layers, the total thickness of the epitaxial layer 20 may be formed within a range of 1 μm to 12 μm.

Referring to FIG. 1B, a mask process and an etching process may be performed on the epitaxial layer 20 to form a trench 30. The trench 30 may be formed to a predetermined depth from an upper surface of the epitaxial layer 20, for example, within a range of 1 μm to 8 μm. Depending on the intensity of the etching process, the trench 30 may become progressively narrower as it deepens toward the semiconductor substrate 10. That is, a width of the entrance (w1) of the trench 30 is wider than a lower width (w2). The sidewall slope of the trench 30 may be formed at an angle of about 85° to 90° with respect to the upper inner surface of the trench 30, and at an angle of about 90° to 95° with respect to the upper outer surface of the trench 30. The trench 30 may be formed in various shapes depending on the etching angle, for example, in a U-shape, V-shape, or other configurations.

However, depending on the degree of etching, the width of the entrance (w1) and the lower width (w2) of the trench 30 may be formed to be the same.

Meanwhile, in FIG. 1B, a sacrificial oxide (not shown in the drawing) may be further formed on the sidewall of the trench 30. The sacrificial oxide is intended to prevent damage (micro damage) or non-uniformity that may occur on the sidewall of the trench 30 during the etching process. Therefore, the sacrificial oxide may be removed once the etching process is completed. This sacrificial oxide may be formed with a thickness of 100 Å to 1500 Å by performing a thermal process at a temperature of approximately 900° C. and 1200° C.

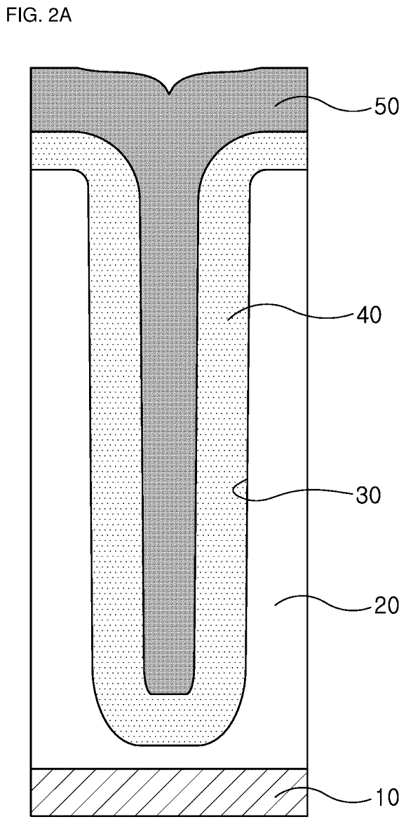

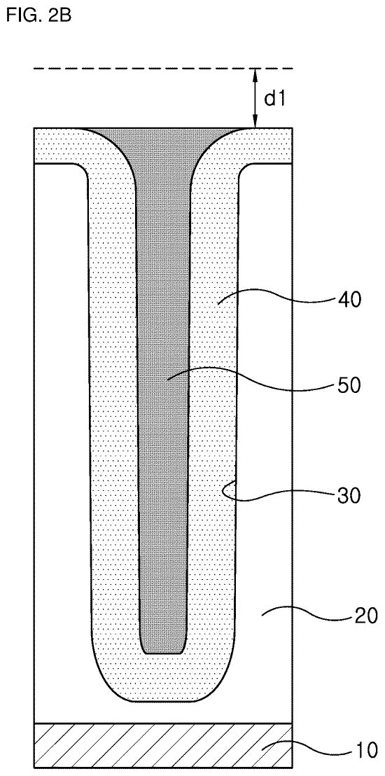

FIG. 2A illustrates a process for forming a shield oxide and a shield poly within the trench.

Referring to FIG. 2A, a shield oxide 40 is formed in the interior of the trench 30 and on the upper surface of the epitaxial layer 20. The shield oxide 40 may be formed by sequentially performing a primary thermal oxidation process and a secondary CVD process. The secondary CVD process may be carried out by one of the following methods: sub atmospheric pressure CVD (SACVD), low pressure CVD (LPCVD), plasma enhanced CVD (PECVD), or high density plasma CVD (HDPCVD).

The shield oxide 40 may include silicon oxide formed by the primary thermal oxidation process and an oxide layer or a nitride layer formed by the secondary CVD process, or it may include a structure in which an oxide and a nitride layer are stacked on the silicon oxide. This shield oxide 40 may have a thickness ranging from 800 Å to 7000 Å.

After the shield oxide 40 is formed, a shield poly 50 is formed on top of it. As shown in the figure, the shield poly 50 is formed with a predetermined thickness both inside the trench 30 and on the upper surface of the epitaxial layer 20. In this example, the thickness of the shield poly 50 may range from 0.3 μm to 8 μm.

FIG. 2B illustrates a process for removing the shield poly.

Specifically, after the shield poly 50 is formed as shown in FIG. 2A, a first chemical mechanical polishing (CMP) process is performed to remove the shield poly 50 located on the upper surface of the shield oxide 40. That is, the shield poly 50 is removed by a thickness of d1. As a result, after the first CMP process, the shield poly 50 remains only within the trench 30.

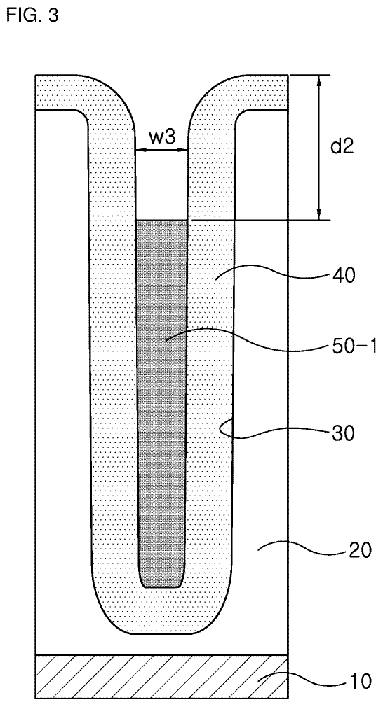

FIG. 3 illustrates a process for performing recess etching on the shield poly.

Referring to FIG. 3, a recess etching process is performed to partially remove the shield poly 50. Specifically, the shield poly 50 is removed downward from the entrance of the trench 30 by a predetermined thickness d2. As a result, in FIG. 3, a remaining shield poly 50-1 remains only in part of the trench 30. The shield poly 50-1, which partially remains within the trench 30, functions as a shield electrode. Furthermore, the thickness of the inter-poly oxide (IPO) to be formed later may be determined based on the depth to which the shield poly 50 is recessed during the recess etching process.

Although not explicitly shown in the drawings, after the recess etching process of FIG. 3, a partial etching process may further be performed. The partial etching process involves etching the shield oxide 40 formed on the sidewall of the trench 30 that are not overlapped with the shield poly 50-1. By performing this process, the width of the aperture (i.e., region w3) of the shield oxide 40 may be further increased. Consequently, the inter-poly oxide (IPO) to be formed in subsequent processes may be more easily formed within the shield oxide 40 and the trench 30. In an example, the partial etching process may be performed using wet etching, dry etching, or a combination of wet and dry etching techniques.

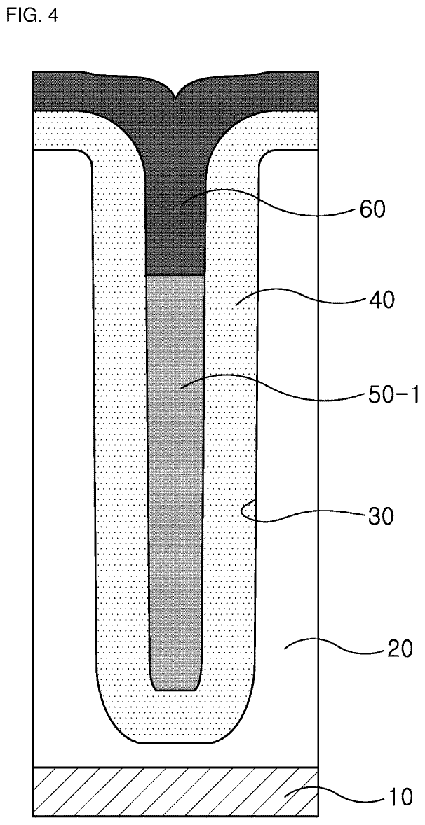

FIG. 4 illustrates a process for forming an inter-poly oxide (IPO).

Referring to FIG. 4, an IPO 60 is formed over the shield poly 50-1 and the shield oxide 40. Accordingly, the IPO 60 is formed not only within the trench 30 but also on the upper surface of the shield oxide 40. The IPO 60 may be formed with a thickness ranging from 3000 Å to 15000 Å. In addition, the IPO 60 may be formed from the same material as the shield oxide 40 or from a different material.

In one example, the IPO 60 is formed using a CVD process, and more specifically, the IPO 60 may be formed by a sub-atmospheric pressure CVD (SACVD) process among the CVD process. In addition, the CVD process may include one of the following: plasma enhanced CVD (PECVD), high-density plasma CVD (HDPCVD), or low-pressure CVD (LPCVD).

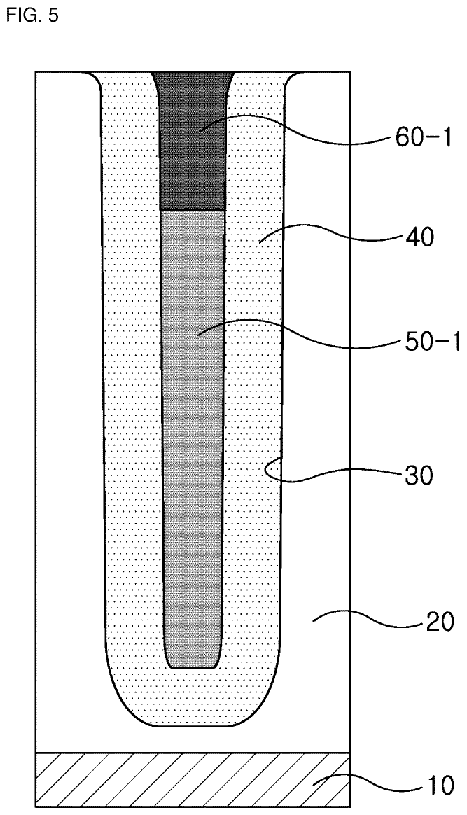

FIG. 5 illustrates a process in which a second CMP process is performed to remove the shield oxide 40 and IPO 60 up to the upper surface of the epitaxial layer 20.

As shown in FIG. 5, the shield oxide 40 and IPO 60 are removed to the upper surface of the epitaxial layer 20 to form a flat surface with the upper surface of the epitaxial layer 20. The shield oxide 40 and IPO 60-1 remain only in the trench 30.

FIG. 5 shows the shield oxide 40 completely removed from the upper surface of the epitaxial layer 20, but the CMP process may be performed to leave some of the shield oxide 40 behind.

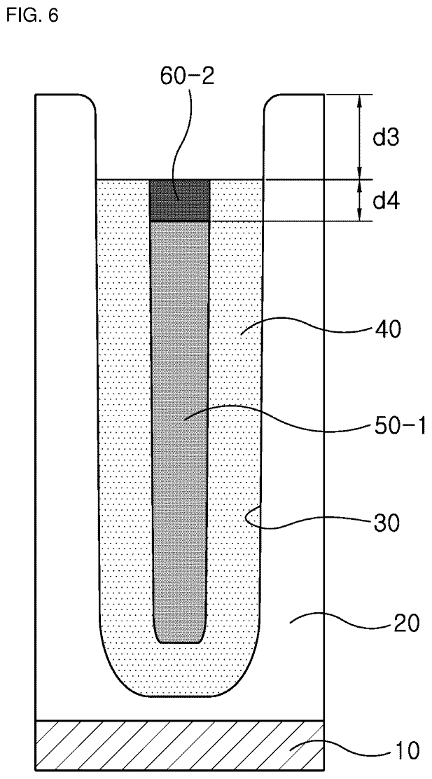

FIG. 6 illustrates a process for adjusting the thickness of the IPO within the trench.

As shown in FIG. 6, the shield oxide 40 and IPO 60-1 remaining in the trench 30 are recess-etched by a thickness of d3, thereby removing a portion of these layers. As a result, the IPO 60-2 with a thickness of d4 is left on the shield poly 50-1. Therefore, the recess etching process serves to control the thickness d4 of the IPO 60-2. The thickness d4 of the IPO 60-2 may be adjusted appropriately according to the performance and capacitance of the trench MOSFET device.

In this example, the thickness d4 of the IPO 60-2 may range from 1000 Å to 5000 Å. The recess etching process may be performed using wet etching, dry etching, or a combination of the wet and dry etching.

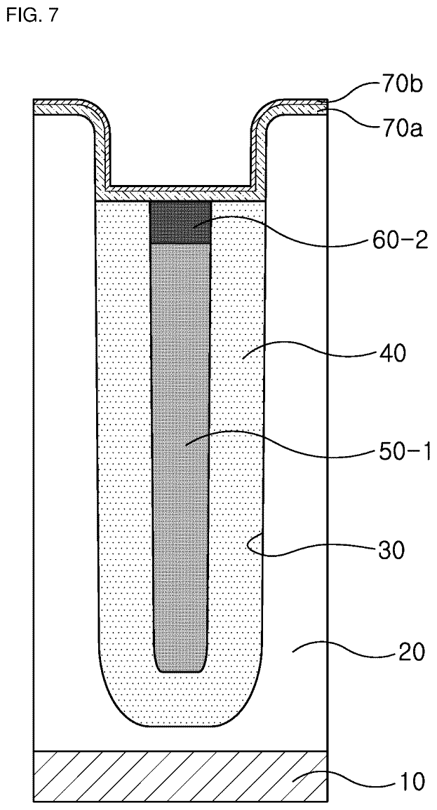

FIG. 7 illustrates a process for forming a first gate sacrificial oxide and a second gate sacrificial oxide.

The process of FIG. 7 is performed to create a gradual boundary between the sidewall of the trench 30 and the upper surface of the shield oxide 40 during the removal of the IPO and shield oxide from the previous processes. To achieve this, FIG. 7 includes a first process for forming a first gate sacrificial oxide 70a, followed by a second process for forming a second gate sacrificial oxide 70b. The second process is carried out after the first process has been completed.

The first process involves forming the first gate sacrificial oxide 70a by high-temperature low-pressure deposition (HLD) in a thickness ranging from 300 Å to 1500 Å. The second process involves forming the second gate sacrificial oxide 70b on top of the first gate sacrificial oxide 70a in a thickness ranging from 200 Å to 600 Å. The second process may be performed by thermal oxidation at a temperature ranging from 850° C. to 950° C. The thermal oxidation process may include dry oxidation, wet oxidation, or steam oxidation. Among these thermal oxidation methods, steam oxidation provides the highest oxidation rate, making it the most effective method for performing the second process in terms of process speed. The thermal oxidation process serves to reduce micro damage on the trench surface caused by the IPO etching process and to anneal the first gate sacrificial oxide 70a.

As described in this example, by further including the process of forming the first gate sacrificial oxide 70a and the second gate sacrificial oxide 70b within the trench 30, it is possible to prevent the formation of concave bottom corners within the trench as described later.

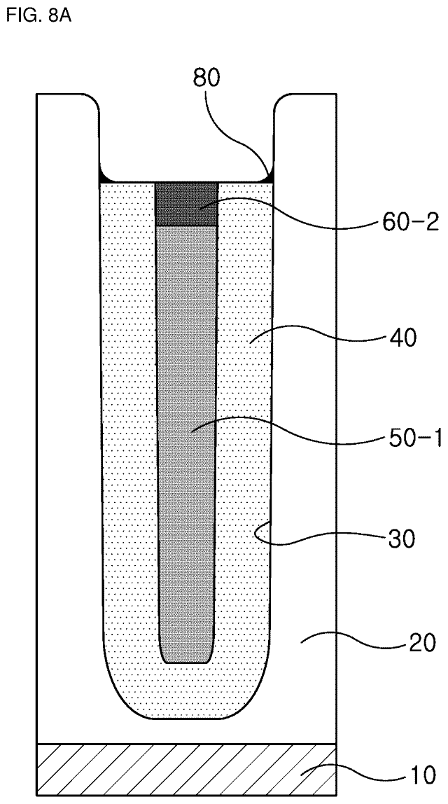

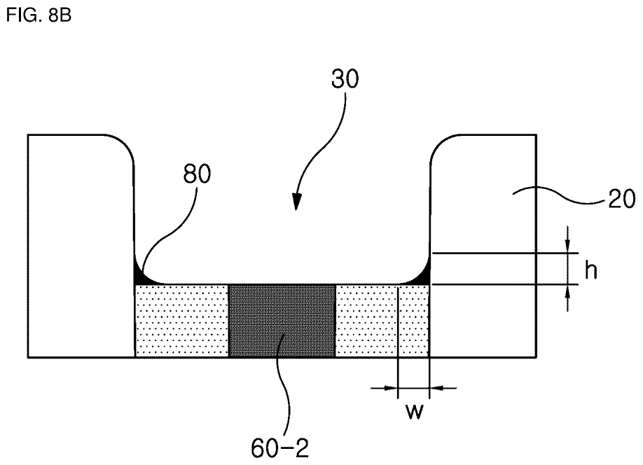

FIGS. 8A and 8B illustrate a process in which the first gate sacrificial oxide and the second gate sacrificial oxide are formed only at the bottom corner of a trench.

To achieve this, an etching process is performed to remove the first gate sacrificial oxide 70a and the second gate sacrificial oxide 70b. As shown in FIG. 8A, the first and second gate sacrificial oxides 70a and 70b located on the upper surface of the epitaxial layer 20, the sidewall of the trench 30, the upper surface of the shield oxide 40, and the upper surface of the IPO 60-2 are removed by the etching process, leaving only the first and second gate sacrificial oxides 70a and 70b at the bottom corner indicated by reference numeral 80. The first gate sacrificial oxide 70a and the second gate sacrificial oxide 70b, labeled as reference numeral 80, remain only at the bottom corner of the trench. The etching process may use wet etching. In the detailed description provided later, a gate sacrificial oxide 80 refers to the first and second gate sacrificial oxides 70a and 70b that remain after the wet etching. The amount of etching is controlled so that the gate sacrificial oxide 80 is formed in a gradual circular arc curve during wet etching. In the wet etching, a buffered oxide etching (BOE) solution may be used. The BOE solution may be prepared by mixing HF (1.75 wt %) and NH₄F (1.7 wt %), and the concentration of these substances may be adjusted to control the etch rate of the wet etching. The etch rate of the wet etching using the BOE solution of the present disclosure may be 7.6 Å/sec. The etch rate may be adjusted according to factors such as the thickness of the first gate sacrificial oxide 70a, the thickness of the second gate sacrificial oxide 70b, and the temperature during the formation of the second gate sacrificial oxide 70b.

FIG. 8B illustrates an enlarged view of the bottom corner of the trench.

As shown in FIG. 8B, the boundary between the sidewall inside the trench 30 and the upper surface of the shield oxide 40 is formed as a smooth, curved arc. At this point, the height (h) and width (w) of the gate sacrificial oxide 80 may be adjusted by controlling the wet etching process time. In this example, the height (h) of the gate sacrificial oxide 80 may range from about 500 Å to 2000 Å, and the width (w) may range from 300 Å to 1800 Å.

By forming the gate sacrificial oxide 80 having the shape described above at the bottom corner of the trench 30, the entire thickness of the gate oxide can be maintained uniformly in subsequent processes even if the gate oxide is formed.

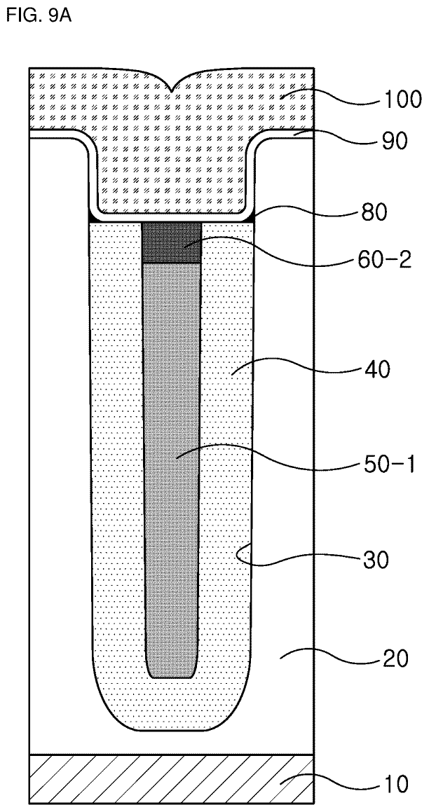

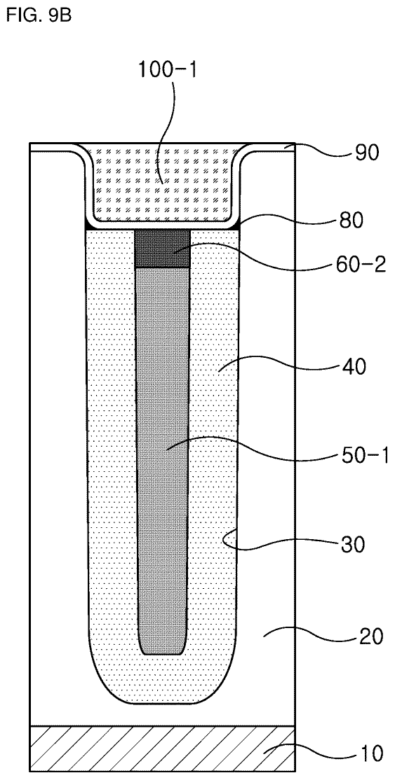

FIG. 9A illustrates a process for forming an insulating layer for a gate poly and the gate poly itself.

Referring to FIG. 9A, a gate oxide 90 which acts as the insulating layer of the gate poly is formed to a predetermined thickness on the upper surface of the epitaxial layer 20 and within the trench 30. In this example, the thickness of the gate oxide 90 may range from about 100 Å to 1000 Å. The gate oxide 90 may be formed using a thermal oxidation process, or using a combination of a thermal oxidation process and a high-temperature low-pressure deposition (HLD) process.

In the present disclosure, before forming the gate oxide 90, the first gate sacrificial oxide 70a and the second gate sacrificial oxide 70b are first formed as described in reference to FIG. 7. Then, the wet etching shown in FIG. 8A is applied to refine the profile of the bottom corner of the trench. As a result, even when the gate oxide 90 is formed using a thermal oxidation process or a combination of a thermal oxidation process and HLD, the thickness of the gate oxide 90 can be uniformly formed. In contrast, in conventional method, when the gate oxide is formed in the same manner, the bottom corner of the trench tends to be formed with a concave curvature.

As shown in FIG. 9A, after the gate oxide 90 is formed to a predetermined thickness, a gate poly 100 is formed on top of it. The gate poly 100 is formed to a predetermined thickness both within the trench 30 and on the upper surface of the epitaxial layer 20.

FIG. 9B illustrates a process for removing the gate poly.

Through the third CMP process, the gate poly 100 is removed to the upper surface of the epitaxial layer 20. As a result, the gate poly 100-1 remains only in the trench 30. At this time, the CMP process may be performed so that a portion of the gate oxide 90 remains on the upper surface of the epitaxial layer 20.

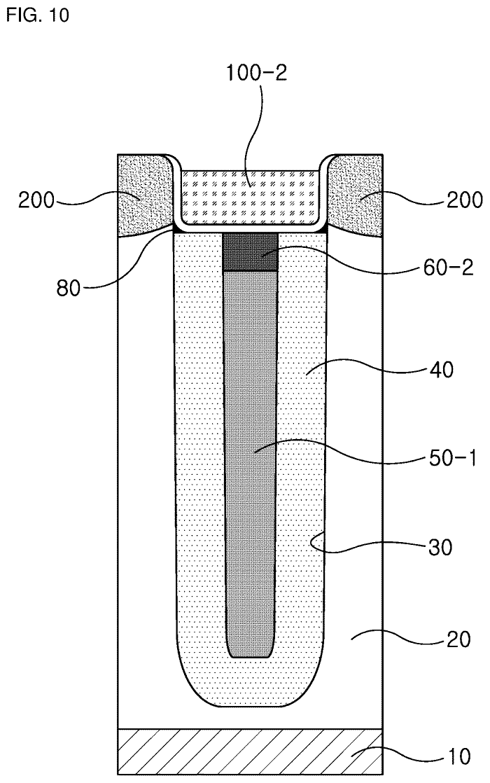

FIG. 10 illustrates a process for forming a body region.

To form the body region 200, the gate poly 100-1 is recessed through an etching process. Specifically, as shown in FIG. 10, the gate poly 100-1 is recess-etched from the upper surface of the epitaxial layer 20 into the trench 30. As a result, the recess-etched gate poly has a shape that extends deeper than the upper surface of the epitaxial layer 20. The recessed gate poly after recess-etching is denoted by reference numeral 100-2. The recess-etched gate poly 100-2 will later be used as a gate electrode, and its thickness will be determined by the duration of the recess etching process. According to this example, the thickness of the remaining gate poly 100-2 after the recess etching process may range from 4000 Å to 8000 Å.

After the gate poly 100-2 is formed, the body region 200 is formed. The body region 200 is located between the trenches 30 and is shown in the figure on the outer upper side of the trench 30. The body region 200 is formed by implanting a second conductivity type (e.g., P-type) different from that of the semiconductor substrate 10 and the epitaxial layer 20. For example, it may be formed through ion implantation of dopant impurities such as boron (B) or boron fluoride (BF₂).

The body region 200 may be formed through a single implantation process or through two or more implantation processes. In the case where two or more implantation processes are performed, the body region 200 may include a first body region and a second body region. At this time, the heights of the first and second body regions may be different from each other, and the dopant concentration may also be adjusted differently during the formation process.

The upper part of the body region 200 may be positioned higher than the gate poly 100-2 inside the trench 30.

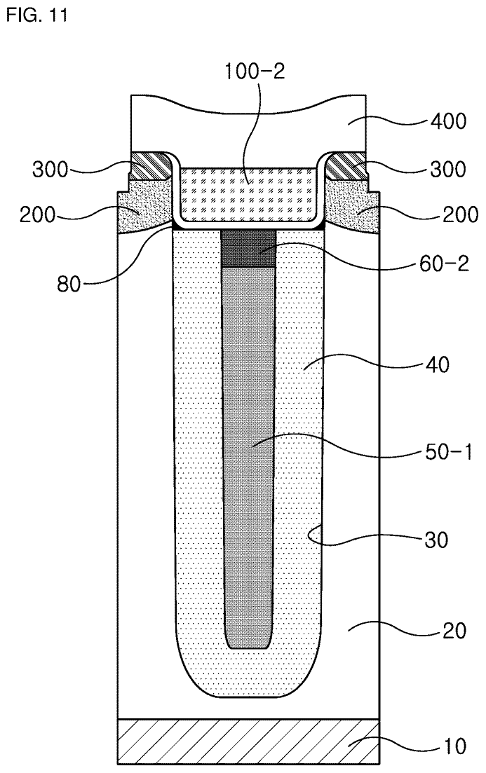

FIG. 11 illustrates a process of forming a source region and an interlayer dielectric.

The source region 300 may be formed through a source photopatterning process. The source photo pattern (not shown) ensures that the source region 300 is formed only in the active region where the source region 300 is to be located, and prevents its formation in termination regions and other areas.

After forming the source photo pattern, the first conductivity type (i.e., N-type) is implanted opposite to the body region 200 to form the source region 300. For example, arsenic (As) or phosphorus (P) may be used as dopants. At this point, the upper surface of the body region 200 is located below the upper surface of the gate poly 100-2. After forming the source region 300, the source photo pattern is removed.

Once the source region 300 is formed, an interlayer dielectric (ILD) 400 is deposited over the gate poly 100-2 and source region 300. In this example, the interlayer dielectric 400 may include both a lower interlayer dielectric and an upper interlayer dielectric. The lower interlayer dielectric may be formed using the high temperature low pressure deposition (HLD) method, and the upper interlayer dielectric may be formed using tetra ethyl ortho silicate (TEOS) or boro phosphoro silicate glass (BPSG) method.

When forming both the lower and upper interlayer dielectrics, they may have different thicknesses. For example, the lower interlayer dielectric may have a thickness of 1000 Å to 3000 Å. The upper interlayer dielectric may have a thickness of 1000 Å to 5000 Å for the TEOS method. When using the TEOS method to form the upper interlayer dielectric, first a TEOS layer with a thickness of 5000 Å to 15000 Å is deposited, and then a CMP process is performed to remove a portion of the TEOS layer. After a portion of the TEOS layer is removed, the upper interlayer dielectric is formed together with the lower interlayer dielectric to a thickness of 2000 Å to 8000 Å. In contrast, when using the BPSG method to form the upper interlayer dielectric, the BPSG layer is deposited to a thickness of 1000 Å to 5000 Å and then annealed to complete its formation.

Therefore, the combined thickness of the upper and lower interlayer dielectrics is between 2000 Å and 8000 Å. In other words, the interlayer dielectric (400) has a thickness ranging from 2000 Å to 8000 Å.

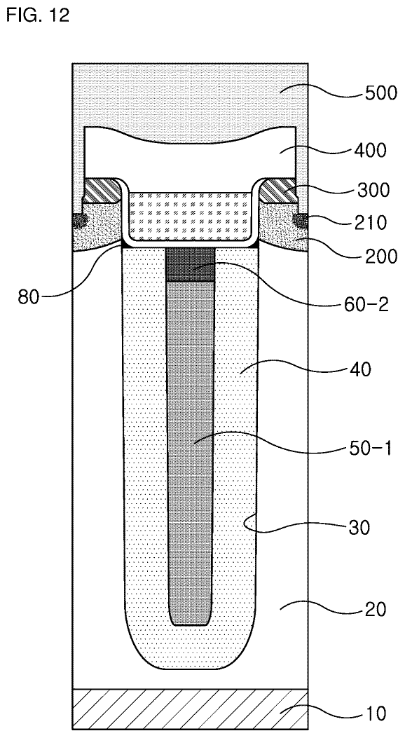

FIG. 12 illustrates a process of forming a body contact region and metal layer. Referring to FIG. 12, a body contact region 210 is formed within the body region 200. The body contact region 210 is formed by ion implantation of a high-concentration second conductivity type (i.e., P+) with a higher concentration than the body region 200.

After forming the body contact region 210, a metal layer 500 is formed to cover the interlayer dielectric (ILD) 400, the source region 300, and the body region 200. The metal layer 500 may be formed by depositing it to a predetermined thickness and then performing a CMP process. This metal layer 500 acts as the source electrode and may be made of metal materials such as aluminum (Al), tungsten (W), or copper (Cu).

Additionally, a passivation layer (not shown) may be formed on top of the metal layer 500 for device protection.

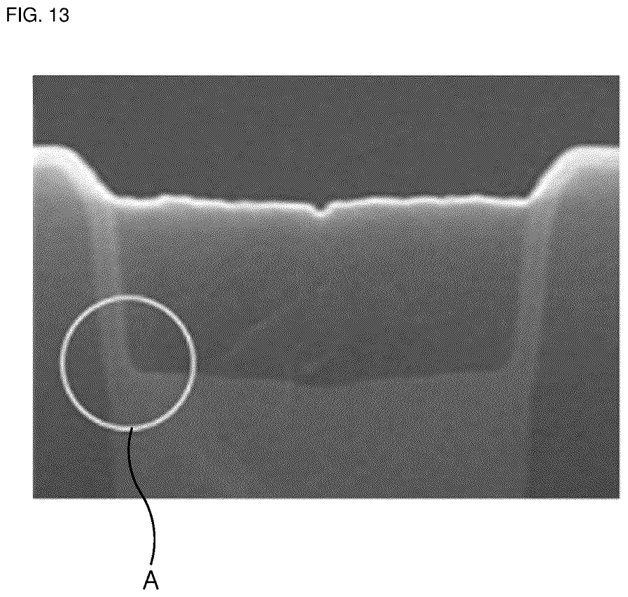

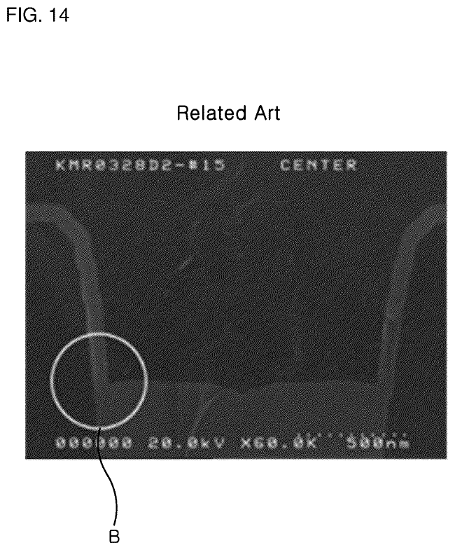

FIGS. 13 and 14 are SEM cross-sectional photographs comparing the structure of the trench MOSFET device of the present disclosure with the structure of a conventional trench MOSFET device.

As illustrated in FIG. 13, the SEM cross-sectional image of the trench MOSFET device of the present disclosure, which was fabricated according to the above described manufacturing process, shows that the boundary between the trench sidewall and the surface of the shield oxide, especially at the bottom corner portion (portion A), is formed as a smooth curve. As a result, the gate oxide at the bottom corner portion (portion A) does not need to be formed excessively thick.

On the other hand, referring to the SEM cross-sectional image of the conventional trench MOSFET device in FIG. 14, it can be seen that the bottom corner portion (portion B) is formed in a concave shape. This, as mentioned earlier, creates the problem of having to thicken the gate oxide that forms inside the trench as a whole.

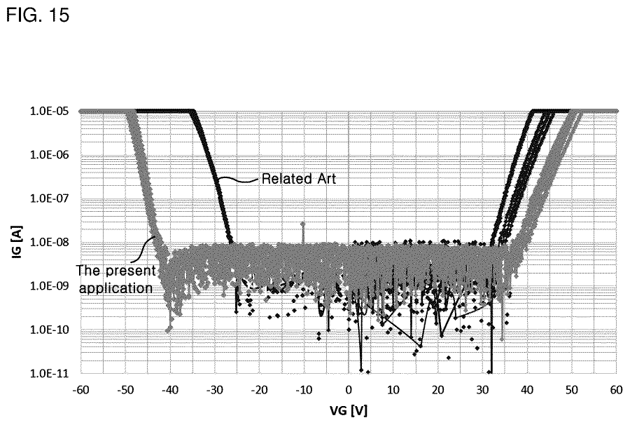

FIG. 15 is a graph comparing the performance of the trench MOSFET device of the present disclosure and the conventional trench MOSFET device. FIG. 15 shows an IG-VGS curve, which shows that the BVGSS spread has improved. For example, for a specific trench MOSFET product, the thickness of the gate oxide was improved by more than 20V in the BVGSS at different positions within the same wafer, from 800 Å/1000 Å. Therefore, the thickness of the gate oxide has been reduced from 800 Å/1000 Å to 675 Å/800 Å at the voltage that guarantees the same BVGSS, resulting in a 15.6% and 20% reduction, respectively. There is also the added benefit of an increased FN-Tunneling region.

The FN-tunneling and BVGSS values before and after applying the bottom corner profile according to the present disclosure can be summarized as shown in Table 1 below.

TABLE 1

| | FN-Tunneling | FN-Tunneling | BVGSS(+) | | BVGSS(−) | |
|---|---|---|---|---|---|---|
| IG-VGS | @ +10 nA | @ −10 nA | @10 μA | | @10 μA | |
| Related art | +26~45 V | −20~−31 V | +28~50 | V | −26 | V |
| The present disclosure | +36~60 V | −43~−50 V | >+50 | V | >−48 | V |

According to the present disclosure, when manufacturing a trench MOSFET device, the profile of the gate sacrificial oxide formed at the bottom corner of the trench is improved by forming a first gate sacrificial oxide layer, subsequently forming a second gate sacrificial oxide layer thereon, and performing a wet etching process prior to forming the gate oxide.

Accordingly, the thickness uniformity of the gate oxide formed at the bottom corner of the trench is improved, and not only the thickness variation of the gate oxide but also the BVGSS and IGSS variations can be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method for manufacturing a trench MOSFET device, the method comprising:
forming an epitaxial layer on a semiconductor substrate;
forming a trench in the epitaxial layer;
forming a shield oxide and a shield poly in the trench;
etching the shield poly in the trench to leave only a portion of the shield poly;
forming an inter poly oxide (IPO) on the shield oxide and the shield poly;
etching the IPO and the shield oxide in the trench, leaving a portion of the IPO on an upper surface of the shield poly and the shield oxide;
forming a first gate sacrificial oxide layer having a first thickness on upper surfaces of the epitaxial layer, the IPO, and the shield oxide in the trench by performing a deposition process;
forming a second gate sacrificial oxide layer having a second thickness thinner than the first thickness on the first gate sacrificial oxide layer by performing a thermal oxidation process; and
performing an etching process to leave a gate sacrificial oxide layer at a boundary between a sidewall of an interior of the trench and the upper surface of the shield oxide.

2. The manufacturing method of claim 1, wherein the first gate sacrificial oxide layer is formed by performing a high-temperature low-pressure deposition (HLD) process.

3. The manufacturing method of claim 1, further comprising:
forming a gate oxide in the interior of the trench and on the upper surface of the epitaxial layer, with the gate sacrificial oxide layer formed at the boundary between the sidewall of the interior of the trench and the upper surface of the shield oxide;
forming a gate poly on the gate oxide;
forming a body region at an upper outer part of the trench; and
forming a source region above the body region and a body contact region in the body region.

4. The manufacturing method of claim 1, wherein, in the etching of the shield poly, a thickness of the IPO is determined by a depth to which the shield poly is etched.

5. The manufacturing method of claim 1, wherein a thickness of the IPO is adjusted in the etching of the IPO and the shield oxide.

6. The manufacturing method of claim 1, wherein the gate sacrificial oxide layer is formed in an arc shape with a predetermined inclination angle at the boundary between the sidewall of the interior of the trench and the upper surface of the shield oxide.

7. The manufacturing method of claim 1, wherein the second gate sacrificial oxide layer is formed using one of thermal oxidation methods of dry oxidation, wet oxidation, or steam oxidation.

8. The manufacturing method of claim 1, wherein etching of areas other than the boundary between the sidewall of the interior of the trench and the upper surface of the shield oxide is performed using wet etching.

9. The manufacturing method of claim 8, wherein a solution used for the wet etching is a mixture of HF and NH₄F.

10. The manufacturing method of claim 1, further comprising:
etching a portion of the shield oxide formed on the sidewall of the trench that does not come into contact with the shield poly to expand an inlet width of the shield oxide.

11. The manufacturing method of claim 1, wherein the first thickness is in a range of 300 Å to 1500 Å, and the second thickness is in a range of 200 Å to 600 Å.

12. The manufacturing method of claim 3, wherein the gate oxide is formed by a thermal oxidation process or a combination of the thermal oxidation process and a HLD process.

13. The manufacturing method of claim 3, wherein an upper surface of the gate poly is formed higher than an upper surface of the body region.

14. The manufacturing method of claim 3, wherein the semiconductor substrate, the epitaxial layer, and the source region are formed with a first conductivity type, and the body region and the body contact region are formed with a second conductivity type different from the first conductivity type.

15. A method for manufacturing a trench MOSFET device, the method comprising:
forming an epitaxial layer on a semiconductor substrate;
forming a first trench in the epitaxial layer;
forming a shield oxide and a shield poly in the first trench;
etching a portion of the shield oxide to form a second trench on a side surface of the shield poly;
forming a first gate sacrificial oxide layer having a first thickness in an interior of the second trench and on an upper surface of the epitaxial layer by performing a deposition process;
forming a second gate sacrificial oxide layer having a second thickness thinner than the first thickness on the first gate sacrificial oxide layer by performing a thermal oxidation process; and
performing an etching process to leave a gate sacrificial oxide layer at a boundary between a sidewall of the interior of the second trench and an upper surface of the shield oxide.

16. The manufacturing method of claim 15, wherein the etching is performed by wet etching.

17. The manufacturing method of claim 15, wherein the first gate sacrificial oxide layer is deposited by performing a high-temperature low-pressure deposition (HLD) process.

18. The manufacturing method of claim 15, further comprising:
forming a gate oxide in the interior of the second trench and on the upper surface of the epitaxial layer to cover the gate sacrificial oxide layer;
forming a gate poly on the gate oxide;
forming a body region at an upper outer portion of the first trench; and
forming a source region above the body region and a body contact region in the body region.

19. The manufacturing method of claim 15, wherein the first thickness is in a range of 300 Å to 1500 Å, and the second thickness is in a range of 200 Å to 600 Å.

20. The manufacturing method of claim 15, wherein the second gate sacrificial oxide layer is formed using one of thermal oxidation methods of dry oxidation, wet oxidation, or steam oxidation.
